(19) United States
(12) Patent Application Publication
(10) Pub. No.: US 2025/0287747 A1
(43) Pub. Date: Sep. 11, 2025

(54) EPITAXIAL DIE FOR SEMICONDUCTOR LIGHT-EMITTING DEVICE, SEMICONDUCTOR LIGHT-EMITTING DEVICE INCLUDING SAME, AND MANUFACTURING METHODS THEREOF

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR)

(73) Assignee: WAVELORD CO., LTD, Hwaseong-si (KR)

(21) Appl. No.: 18/860,630

(22) PCT Filed: Sep. 18, 2023
(86) PCT No.: PCT/KR2023/014067

§ 371 Date: Oct. 26, 2024

(30) Foreign Application Priority Data
Sep. 19, 2022 (KR) 10-2022-0117788
Dec. 7, 2022 (KR) 10-2022-0169551

(51) Int. Cl. H10H 20/857; H10H 20/01; H10H 20/84

(52) U.S. Cl. CPC H10H 20/857; H10H 20/034; H10H 20/0364; H10H 20/84

(57) ABSTRACT

The present invention relates to an epitaxial die for a semiconductor light-emitting device emitting red light, a semiconductor light-emitting device including same, and manufacturing methods thereof, wherein in the epitaxial die only one of two electrodes is exposed to the outside, and a process of forming an ohmic contact electrode can be completed in an epitaxial die manufacturing step.

### TECHNICAL FIELD

The present invention relates to an epitaxial die for a semiconductor light-emitting device and a semiconductor light-emitting device including the same.

### BACKGROUND ART

In general, micro light-emitting diode (LED) displays (including mini LED displays) can be classified into micro LED displays with a passive matrix (PM) driving method and micro LED displays with an active matrix (AM) driving method.

Here, PM-driven micro LED displays typically have a sapphire support substrate, which finally remains, and use sorted thick BGR (Blue, Green, and Red) chips (with both fully fabricated positive and negative electrodes of the LED), which are transferred using a chip die-level process in which either horizontal chips or flip chips can be generally utilized.

In addition, AM-driven micro LED displays typically do not have a sapphire support substrate, which finally remains, and use unsorted thin BGR (Blue, Green, and Red) chips (with both fully fabricated positive and negative electrodes of the LED), which are transferred using a wafer-level process in which horizontal chips, flip chips, or vertical chips can all be generally utilized.

These conventional typical PM- and AM-driven micro LED displays have the following common issues.

First, when considering the application of vertical chips to reduce chip die size, there is a problem that, unlike flip chips, which allow defects to be immediately confirmed after bonding, in the case of vertical chips, defects can only be confirmed after bonding and subsequent top-level wiring.

Further, in terms of a bonding process, higher precision is required in the bonding process due to the reduction in chip die size, and improved bonding strength is required due to the reduction in bonding area.

Further, in terms of a tiling process in which a plurality of unit displays are combined like tiles, there is an issue in which boundaries between the unit displays become distinct when the displays are turned off or show a black screen, and this is more noticeable in the PM driving method compared to the AM driving method. In addition, although many aspects have been improved, there is still an issue in which boundaries are visible on monochromatic screens and still images, and when using thin-film transistor (TFT) glass panels for tiling, the process is challenging due to the risk of glass breakage. Furthermore, due to the tolerance relationship between pixel pitch and tiling boundaries, various issues exist, including the expectation that the tiling process will be difficult to apply to products smaller than 100 inches.

Meanwhile, in the conventional PM-driven micro LED displays, the reduction in chip die size is the greatest challenge. That is, from an aspect ratio perspective, achieving a reduction in chip die size essentially requires decreasing a thickness of a sapphire final support substrate, but the current limit for the thickness of the sapphire support substrate is about 80 μm to 70 μm, and when reducing the thickness below 50 μm, a substrate breaking issue occurs. Further, there are complex issues related to chip measurement and classification in this type of micro LED display, and it is expected that flip chips will be mainly used in this type of display rather than horizontal and vertical chips, but when the flip chips are used, high-precision and high-speed bonding processes, as well as materials for them, are separately required.

Further, in conventional AM-driven micro LED displays, in which the final support substrate is not present and chip die size reduction is possible, there are issues related to resolving defects (No Good, NG). That is, the fundamental issues in epitaxy and fab processes, such as yield improvement related to wavelength and electrical characteristics at the chip-on-wafer (COW) level, have not been resolved, and there is difficulty in 100% sorting and removal of defective (NG) chips. In order to address these issues, approaches such as redundancy have been recently attempted, but have not provided a fundamental solution.

### DISCLOSURE

### Technical Problem

The present invention is directed to solving the above-mentioned conventional problems and providing an epitaxial die for a semiconductor light-emitting device that emits red light, in which only one of two electrodes is exposed to the outside, and a process of forming a p-ohmic contact electrode or an n-ohmic contact electrode is completed at the operation of manufacturing the epitaxial die, thereby enabling a significant reduction in thickness and chip die size to improve light output, a semiconductor light-emitting device including the same, and a method of manufacturing the same.

### Technical Solution

One aspect of the present invention provides an epitaxial die for a semiconductor light-emitting device, the epitaxial die including a light-emitting part configured to generate red light, a first ohmic electrode formed on the light-emitting part and electrically connected to the light-emitting part, a contact electrode formed on the first ohmic electrode and electrically connected to the first ohmic electrode, a temporary bonding layer formed to cover the contact electrode, a temporary substrate bonded on the temporary bonding layer, and a bonding pad layer formed to come into contact with a lower surface of the light-emitting part to be electrically connected to the light-emitting part and functioning as a vertical chip bonding pad, wherein the contact electrode is interposed between the temporary bonding layer and the first ohmic electrode and thus is not exposed.

Another aspect of the present invention provides a semiconductor light-emitting device including a substrate part on which a first electrode pad and a second electrode pad are each formed, an epitaxial die that includes a light-emitting part configured to generate red light, a first ohmic electrode formed on the light-emitting part and electrically connected to the light-emitting part, a contact electrode formed on the first ohmic electrode and electrically connected to the first ohmic electrode, and a bonding pad layer that is formed to come into contact with a lower surface of the light-emitting part to be electrically connected to the light-emitting part, functions as a vertical chip bonding pad, and is placed on the first electrode pad, a bonding layer bonding and electrically connecting the first electrode pad and the bonding pad layer, an extension electrode electrically connecting the second electrode pad and the contact electrode exposed to the outside, and a mold part surrounding the epitaxial die and the extension electrode.

Still another aspect of the present invention provides a method of manufacturing an epitaxial die for a semiconductor light-emitting device, including a first operation of preparing a growth substrate and a temporary substrate, a second operation of forming a light-emitting part, which generates red light, on the growth substrate, a third operation of forming a first ohmic electrode on the light-emitting part, a fourth operation of forming a passivation layer that covers the first ohmic electrode, a fifth operation of etching a portion of the passivation layer to expose the first ohmic electrode and forming a contact electrode to come into contact with the exposed first ohmic electrode, a sixth operation of bonding the temporary substrate and the passivation layer, in which the contact electrode is exposed, through a temporary bonding layer, a seventh operation of separating the growth substrate, and an eighth operation of forming a bonding pad layer formed to come into contact with a lower surface of the light-emitting part to be electrically connected to the light-emitting part and functioning as a vertical chip bonding pad.

Yet another aspect of the present invention provides a method of manufacturing a semiconductor light-emitting device, including a first operation of preparing an epitaxial die that includes a light-emitting part configured to generate red light, a first ohmic electrode formed on the light-emitting part and electrically connected to the light-emitting part, a passivation layer covering the first ohmic electrode and partially open to expose a portion of the first ohmic electrode, a contact electrode formed on the exposed first ohmic electrode and electrically connected the first ohmic electrode, a temporary bonding layer formed on the passivation layer to cover the contact electrode, a temporary substrate bonded on the temporary bonding layer, and a bonding pad layer formed to come into contact with a lower surface of the light-emitting part to be electrically connected to the light-emitting part and functioning as a vertical chip bonding pad, and preparing a substrate part on which a first electrode pad and a second electrode pad are each formed, a second operation of placing the epitaxial die on the first electrode pad and bonding and electrically connecting the first electrode pad and the bonding pad layer through a bonding layer, a third operation of separating the temporary substrate and etching the temporary bonding layer to expose the contact electrode, a fourth operation of forming a mold part that surrounds the epitaxial die so that the contact electrode is exposed, a fifth operation of etching the mold part so that the second electrode pad is exposed, and a sixth operation of forming an extension electrode that electrically connects the second electrode pad and the exposed contact electrode.

Yet another aspect of the present invention provides an epitaxial die for a semiconductor light-emitting device, including a light-emitting part configured to generate red light, a first ohmic electrode formed on the light-emitting part and electrically connected to the light-emitting part, a bonding pad layer formed on the first ohmic electrode and electrically connected to the first ohmic electrode and functioning as a vertical chip bonding pad, a contact electrode formed to come into contact with a lower surface of the light-emitting part to be electrically connected to the light-emitting part, a temporary bonding layer formed on the lower surface of the light-emitting part to cover the contact electrode, and a temporary substrate bonded to a lower surface of the temporary bonding layer, wherein the contact electrode is interposed between the temporary bonding layer and the light-emitting part and thus is not exposed.

Yet another aspect of the present invention provides a semiconductor light-emitting device including a substrate part on which a first electrode pad and a second electrode pad are each formed, an epitaxial die that includes a light-emitting part configured to generate red light, a first ohmic electrode formed on the light-emitting part and electrically connected to the light-emitting part, a bonding pad layer formed on the first ohmic electrode and electrically connected to the first ohmic electrode and functioning as a vertical chip bonding pad, and a contact electrode that is formed to come into contact with a lower surface of the light-emitting part to be electrically connected to the light-emitting part and is placed upside down on the first electrode pad, a bonding layer bonding and electrically connecting the first electrode pad and the bonding pad layer, an extension electrode electrically connecting the second electrode pad and the contact electrode exposed to the outside, and a mold part surrounding the epitaxial die and the extension electrode.

Yet another aspect of the present invention provides a method of manufacturing an epitaxial die for a semiconductor light-emitting device, including a first operation of preparing a growth substrate, a first temporary substrate, and a second temporary substrate, a second operation of forming a light-emitting part, which generates red light, on the growth substrate and forming a first ohmic electrode on the light-emitting part, a third operation of forming a passivation layer that covers the first ohmic electrode, a fourth operation of etching a portion of the passivation layer to expose the first ohmic electrode and forming a bonding pad layer, which functions as a vertical chip bonding pad, to come into contact with the exposed first ohmic electrode, a fifth operation of bonding the first temporary substrate and the passivation layer, in which the bonding pad layer is exposed, through a first temporary bonding layer, a sixth operation of separating the growth substrate, a seventh operation of forming a contact electrode to come into contact with a lower surface of the light-emitting part, an eighth operation of bonding the second temporary substrate and the lower surface of the light-emitting part, in which the contact electrode is exposed, through a second temporary bonding layer, and a ninth operation of separating the first temporary substrate and etching the first temporary bonding layer to expose the bonding pad layer.

Yet another aspect of the present invention provides a method of manufacturing a semiconductor light-emitting device, including a first operation of preparing an epitaxial die including a light-emitting part configured to generate red light, a first ohmic electrode formed on the light-emitting part and electrically connected to the light-emitting part, a passivation layer covering the first ohmic electrode and partially open to expose a portion of the first ohmic electrode, a bonding pad layer formed on the exposed first ohmic electrode to be electrically connected to the first ohmic electrode and functioning as a vertical chip bonding pad, a contact electrode formed to come into contact with a lower surface of the light-emitting part to be electrically connected to the light-emitting part, a temporary bonding layer formed on the lower surface of the light-emitting part to cover the contact electrode, and a temporary substrate bonded to a lower surface of the temporary bonding layer, and preparing a substrate part on which a first electrode pad and a second electrode pad are each formed, a second operation of placing the epitaxial die upside down on the first electrode pad and bonding and electrically connecting the first electrode pad and the bonding pad layer through a bonding layer, a third operation of separating the temporary substrate and etching the temporary bonding layer to expose the contact electrode, a fourth operation of forming a mold part that surrounds the epitaxial die so that the contact electrode is exposed, a fifth operation of etching the mold part so that the second electrode pad is exposed, and a sixth operation of forming an extension electrode that electrically connects the second electrode pad and the exposed contact electrode.

### Advantageous Effects

According to the present invention, it is possible to simultaneously satisfy both the advantage of a mini light-emitting diode (LED) manufacturing process, such as ease of defect classification, and low process and capital investment costs due to the use of existing general-purpose transfer equipment as is, and the advantage of a micro LED manufacturing process, such as a dramatic reduction in thickness and a reduction in chip die size by removing a sapphire final support substrate, thereby improving light output.

In addition, according to the present invention, unlike conventional chip dies, in which two electrodes, i.e., a positive electrode and a negative electrode, are exposed to the outside, an epitaxial die of the present invention has a structure in which only one electrode is exposed to the outside, and thus, although electrical sorting through an electro luminescence (EL) measurement method is not possible, the epitaxial die can be optically sorted through a high-speed photo luminescence (PL) measurement method, allowing defects (No Good, NG) to be easily identified initially using only optical characteristics (such as wavelength, full-width at half maximum (FWHM), and intensity).

Further, according to the present invention, an epitaxial die of the present invention has the advantage that a process of forming a p-ohmic contact electrode or an n-ohmic contact electrode, which requires high-temperature heat treatment of 300° C. or higher, is completed at the operation of manufacturing the epitaxial die, so that the epitaxial die of the present invention does not require a high-temperature heat treatment process after transfer.

Further, according to the present invention, an epitaxial die of the present invention has the advantage of having a sapphire final support substrate attached, which can be removed after being transferred onto a targeted wafer, thereby enabling the die to be repositioned through conventional chip die transfer processes such as pick-and-place and replace.

Meanwhile, the effects of the present invention are not limited to the above-mentioned effects, and various effects may be included within the scope which is apparent to those skilled in the art from contents to be described below.

### DESCRIPTION OF DRAWINGS

FIG. 1 illustrates an overall view of an epitaxial die for a semiconductor light-emitting device according to a first embodiment of the present invention.

FIG. 2 illustrates an overall view of a semiconductor light-emitting device according to the first embodiment of the present invention.

FIG. 3 is a flowchart of a method of manufacturing the epitaxial die for a semiconductor light-emitting device according to the first embodiment of the present invention.

FIG. 4 illustrates a process of manufacturing the epitaxial die for a semiconductor light-emitting device according to the first embodiment of the present invention.

FIG. 5 is a flowchart of a method of manufacturing the semiconductor light-emitting device according to the first embodiment of the present invention.

FIG. 6 illustrates a process of manufacturing the semiconductor light-emitting device according to the first embodiment of the present invention.

FIG. 7 illustrates an overall view of an epitaxial die for a semiconductor light-emitting device according to a second embodiment of the present invention.

FIG. 8 illustrates an overall view of a semiconductor light-emitting device according to the second embodiment of the present invention.

FIG. 9 is a flowchart of a method of manufacturing the epitaxial die for a semiconductor light-emitting device according to the second embodiment of the present invention.

FIG. 10 illustrates a process of manufacturing the epitaxial die for a semiconductor light-emitting device according to the second embodiment of the present invention.

FIG. 11 is a flowchart of a method of manufacturing the semiconductor light-emitting device according to the second embodiment of the present invention.

FIG. 12 illustrates a process of manufacturing the semiconductor light-emitting device according to the second embodiment of the present invention.

### MODES OF THE INVENTION

Hereinafter, some embodiments of the present invention will be described in detail with reference to exemplary drawings. It should be noted that in adding reference numerals to the components of each drawing, the same components have the same number when possible, even though the same components are shown in different drawings

In addition, in describing the embodiments of the present invention, when detailed descriptions of related known structures or functions may obscure the gist of the present invention, the detailed description thereof will be omitted.

In addition, terms such as first, second, A, B, (a), (b), and the like may be used herein to describe components of the embodiments of the present invention. Each of these terms is not used to define an essence, order, or sequence of a corresponding component but used merely to distinguish the corresponding component from other component(s).

The present invention relates to an epitaxial die for a semiconductor light-emitting device that emits blue, green, or red light, particularly red light, and a semiconductor light-emitting device including the same. In the present invention, a semi-finished light source die with a size less than or equal to that of a mini light-emitting diode (LED), which can be sorted and has the following characteristics, is defined as the epitaxial die of the present invention.

First, unlike conventional chip dies in which two electrodes, i.e., a positive electrode and a negative electrode, are both exposed to the outside, the epitaxial die of the present invention has a structure in which only one electrode is exposed to the outside. Accordingly, since the epitaxial die of the present invention has only one (contact electrode) of the two electrodes exposed to the outside, although the epitaxial die is not electrically sorted by an electro luminescence (EL) measurement method, the epitaxial die can be optically sorted by a high-speed photo luminescence (PL) measurement method, allowing defects (NG) to be detected initially using only optical characteristics (wavelength, full-width half maximum (FWHM), intensity, and the like).

Second, in the epitaxial die of the present invention, a process of forming a p-ohmic contact electrode or an n-ohmic contact electrode, which requires high-temperature heat treatment of 300° C. or higher, is completed at the operation of manufacturing the epitaxial die. Accordingly, the epitaxial die of the present invention has the advantage of not requiring a high-temperature heat treatment process after transfer.

Third, the epitaxial die of the present invention includes a sapphire final support substrate attached thereto, which is removed after transfer. Accordingly, the epitaxial die of the present invention has the advantage of being repositionable through conventional chip die transfer processes such as pick-and-place and replace.

That is, the epitaxial die of the present invention can simultaneously satisfy both the advantage of a mini light-emitting diode (LED) manufacturing process, such as ease of defect classification, and low process and capital investment costs due to the use of existing general-purpose transfer equipment as is, and the advantage of a micro LED manufacturing process, such as a dramatic reduction in thickness and a reduction in chip die size by removing a support substrate, which is the final substrate, thereby improving light output.

Hereinafter, with reference to the accompanying drawings, an epitaxial die 100 for a semiconductor light-emitting device according to a first embodiment of the present invention will be described in detail.

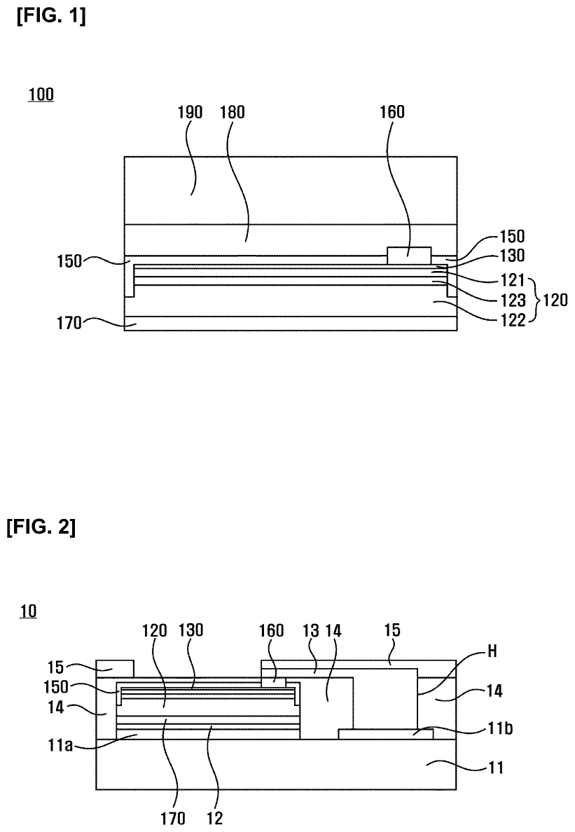

FIG. 1 illustrates an overall view of the epitaxial die for a semiconductor light-emitting device according to the first embodiment of the present invention.

As shown in FIG. 1, the epitaxial die 100 for a semiconductor light-emitting device according to the first embodiment of the present invention includes a light-emitting part 120, a first ohmic electrode 130, a passivation layer 150, a contact electrode 160, a bonding pad layer 170, a temporary bonding layer 180, and a intermediate temporary substrate 190.

The light-emitting part 120 generates light, and in the present invention, in order to emit red light, binary, ternary, and quaternary compounds of Group III (Al, Ga, and In) phosphide semiconductors, such as indium phosphide (InP), indium gallium phosphide (InGaP), gallium phosphide (GaP), aluminum indium phosphide (AlInP), aluminum gallium phosphide (AlGaP), aluminum phosphide (AlP), and aluminum gallium indium phosphide (AlGaInP), are placed in appropriate positions and sequences on an initial growth substrate 110 and epitaxially grown (in the structure of the epitaxial die 100 of the present invention, the initial growth substrate 110 is separated after the intermediate temporary substrate 190 is bonded).

In particular, in order to emit red light, a Group III phosphide semiconductor with a high indium (In) composition, such as high-quality indium gallium phosphide (InGaP), should preferentially be formed on Group III phosphide semiconductors composed of gallium phosphide (GaP), aluminum indium phosphide (AlInP), aluminum gallium phosphide (AlGaP), aluminum phosphide (AlP), and aluminum gallium indium phosphide (AlGaInP), but the present invention is not limited thereto.

More specifically, the light-emitting part 120 includes a first semiconductor region 121 (e.g., a p-type semiconductor region), an active region 123 (e.g., multi-quantum wells (MQWs)), and a second semiconductor region 122 (e.g., an n-type semiconductor region), and the light-emitting part 120 may have a structure in which the second semiconductor region 122, the active region 123, and the first semiconductor region 121 are epitaxially grown in this order on the initial growth substrate 110, and ultimately, may have an overall thickness typically ranging from about 5.0 to 8.0 μm, including multiple layers of group III phosphides, but the present invention is not limited thereto.

Each of the first semiconductor region 121, the active region 123, and the second semiconductor region 122 may be formed as either a single layer or multiple layers, and although not shown in the drawing, necessary layers, such as buffer regions, may be added before epitaxially growing the light-emitting part 120 on the gallium arsenide (GaAs) initial growth substrate 110 to ensure the high quality of the epitaxially grown light-emitting part 120. For example, the buffer regions may include a nucleation layer and a compliant layer composed of an un-doped semiconductor region to relieve stress and improve thin-film quality and typically have a thickness of about 4.0 μm. In addition, since the initial growth substrate 110 must be removed using a chemical lift-off (CLO) technique, it is preferable to grow an etching-stop layer (ESL) composed of gallium indium phosphide (GaInP) as a single-crystal thin film with a thickness of about 200 nm directly on the GaAs initial growth substrate 110 before the doped first semiconductor region 121 or second semiconductor region 122 is formed.

The second semiconductor region 122 has a second conductivity type (n-type), and is formed on the initial growth substrate 110. The second semiconductor region 122 is primarily composed of gallium arsenide (GaAs) and aluminum gallium indium phosphide (AlGaInP) semiconductors, and may have a thickness ranging from 2.0 to 3.5 μm.

The active region 123 generates light, i.e., red light, by using the recombination of electrons and holes, and is formed on the second semiconductor region 122. The active region 123 is composed of multiple layers of semiconductors, including primarily gallium indium phosphide (GaInP) and aluminum gallium indium phosphide (AlGaInP), and may have a thickness of several tens of nanometers (nm).

The first semiconductor region 121 has a first conductivity type (p-type), and is formed on the active region 123. The first semiconductor region 121 is composed of multiple layers of semiconductors, including primarily aluminum indium phosphide (AlInP), aluminum gallium indium phosphide (AlGaInP), and gallium phosphide (GaP), and may have a thickness ranging from several tens of nanometers (nm) to several micrometers (um).

That is, the active region 123 is interposed between the first semiconductor region 121 and the second semiconductor region 122, and light is generated when holes in the first semiconductor region 121, which is a p-type semiconductor region, and electrons in the second semiconductor region 122, which is an n-type semiconductor region, recombine in the active region 123.

Meanwhile, the light-emitting part 120, which is epitaxially grown on the initial growth substrate 110 in the order of the second semiconductor region 122, the active region 123, and the first semiconductor region 121, has a structure in which the first semiconductor region 121, the active region 123, and the second semiconductor region 122 are stacked in that order on the intermediate temporary substrate 190 when the first semiconductor region 121 is bonded to the intermediate temporary substrate 190, which is made of sapphire, through the temporary bonding layer 180.

At this time, both sides of the light-emitting part 120 formed on the initial growth substrate 110 may have a shape etched to a predetermined depth, and the predetermined depth may refer to a depth up to the second semiconductor region 122, but the present invention is not limited thereto.

The first ohmic electrode 130 is electrically connected to the first semiconductor region 121 of the light-emitting part 120 and is formed on the first semiconductor region 121 so as to cover and come into surface contact with an upper surface of the first semiconductor region 121. In this case, the first semiconductor region 121, which is a p-type semiconductor region, is electrically connected to the first ohmic electrode 130 through a p-ohmic contact.

This first ohmic electrode 130 may be basically formed of a material with high transparency and excellent electrical conductivity, but the present invention is not limited thereto. The first ohmic electrode 130 may be made of optically transparent materials such as indium tin oxide (ITO), zinc oxide (ZnO), indium zinc oxide (IZO), indium gallium zinc oxide (IGZO), titanium nitride (TiN), Ni(O)—Au, Ni(O)—AuBe, Ni(O)—Ag, and the like.

The passivation layer 150 covers the first ohmic electrode 130 from the etched portions on both sides of the light-emitting part 120, and a portion of the first ohmic electrode 130 is exposed as a portion of the passivation layer 150 is etched and is opened.

The passivation layer 150 may be implemented with electrically insulating materials, and may include a single layer or multiple layers including at least one material from among silicon oxide, silicon nitride, metallic oxides including Al2O3, and organic insulators.

The contact electrode 160 is electrically connected to the first ohmic electrode 130 and is formed on the first ohmic electrode 130 exposed by opening a portion of the passivation layer 150.

The materials of the contact electrode 160 are not limited as long as they have strong adhesion to the first ohmic electrode 130, but may include Ti, TiN, Cr, CrN, V, VN, NiCr, Al, Rh, Pt, Ni, Pd, Ru, Cu, Ag, Au, AuBe, and the like.

The temporary bonding layer 180 bonds the passivation layer 150 formed as the contact electrode 160 is exposed to the intermediate temporary substrate 190, and is formed above the passivation layer 150 and the contact electrode 160. Due to the shape of the temporary bonding layer 180 that encloses the contact electrode 160, the contact electrode 160 is interposed between the temporary bonding layer 180 and the first ohmic electrode 130 and thus is not exposed.

The temporary bonding layer 180 may include materials such as benzocyclobutene (BCB), SU-8 polymers, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The intermediate temporary substrate 190 is bonded to the passivation layer 150 by the temporary bonding layer 180 to support the light-emitting part 120, the first ohmic electrode 130, the passivation layer 150, the contact electrode 160, and the bonding pad layer 170 to be described below, and it is preferable that the intermediate temporary substrate 190 is formed of a material that has a thermal expansion coefficient equal or similar to that of the initial growth substrate 110 and is simultaneously optically transparent, as long as the difference in thermal expansion coefficient does not exceed 2 ppm. The most preferable materials for the intermediate temporary substrate 190 that meet these criteria may include sapphire, or glass that has been adjusted to have a difference in thermal expansion coefficient of 2 ppm or less from the initial growth substrate 110.

Meanwhile, in the present invention, the intermediate temporary substrate 190 functions as a final support substrate that supports the light-emitting part 120, the first ohmic electrode 130, the passivation layer 150, the contact electrode 160, and the bonding pad layer 170 to be described below after the epitaxial die 100 of the present invention is finally completed. At this time, it is preferable that an LLO sacrificial separation layer (not shown), which is a functional material that can be easily separated and removed by an LLO technique in the process of a third operation of a method (S10) of manufacturing the semiconductor light-emitting device, which will be described below, is formed between the intermediate temporary substrate 190 and the temporary bonding layer 180. The above-described LLO sacrificial separation layer (not shown) may be made of materials such as ZnO, ITO, IZO, IGO, IGZO, InGaN, InGaON, GaON, TiN, SiO2, SiNx, and the like.

The bonding pad layer 170 functions as a vertical chip die bonding pad, and is formed to come into contact with a lower surface of the light-emitting part 120 to be electrically connected to the light-emitting part 120. At this time, the bonding pad layer 170 is electrically connected to a lower surface of the second semiconductor region 122, which is an n-type semiconductor region, through an n-ohmic contact, is exposed to the outside, and functions as a negative electrode while also serving as an active reflector.

It is preferable that the bonding pad layer 170 basically includes three regions (not shown). A first region may include transparent electrically conductive materials (i.e., ITO, IZO, ZnO, IGZO, TiN, and (O)-AuGe) with strong adhesion to the light-emitting part 120. A second region may include highly reflective materials (i.e., Al, Ag, AgCu, Rh, Pt, Ni, and Pd). A third region may include low melting point metals and noble metals such as gold (Au), silver (Ag), copper (Cu), and palladium (Pd), but the present invention is not limited thereto. In addition, the low melting point metals of the bonding pad layer 170 may be formed of metals such as In, Sn, Zn, and Pb alone or an alloy including these metals.

Furthermore, although not shown in the drawing, before forming the bonding pad layer 170 on the lower surface of the light-emitting part 120, a surface texture pattern with a predetermined shape or an irregular shape may be formed on the lower surface of the second semiconductor region 122 to extract as much light generated in the active region 123 into the air as possible.

Accordingly, in the epitaxial die 100 for a semiconductor light-emitting device according to the first embodiment of the present invention, the contact electrode 160 serving as a positive electrode and the first ohmic electrode 130 are interposed between the temporary bonding layer 180 and the light-emitting part 120 and thus are not exposed, and only the bonding pad layer 170 functioning as a negative electrode is exposed to the outside.

Hereinafter, with reference to the accompanying drawings, a semiconductor light-emitting device 10 according to the first embodiment of the present invention will be described in detail.

The semiconductor light-emitting device 10 of the present invention may be formed as a chip-on-board (COB) in which individual chips or epitaxial die units are directly transferred and connected to a substrate (such as a semiconductor wafer, printed circuit board (PCB), or thin-film transistor (TFT) glass) on which circuit wiring and driving element regions are completed, a package-on-board (POB) in which package units (including 1, 2, 4, 9, 16, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using the intermediate temporary substrate 190 on which circuit wiring and driving element regions are not completed, but is not limited thereto, and will be described herein as being formed as the COB type for convenience of description.

FIG. 2 illustrates an overall view of the semiconductor light-emitting device according to the first embodiment of the present invention.

As shown in FIG. 2, the semiconductor light-emitting device 10 according to the first embodiment of the present invention includes a substrate part 11, the epitaxial die 100, a bonding layer 12, an extension electrode 13, a mold part 14, and a black matrix 15.

The substrate part 11 supports the epitaxial die 100 that is bonded thereto, and a first electrode pad 11a and a second electrode pad 11b are each formed on an upper surface of the substrate part 11. The substrate part 11 may refer to a semiconductor wafer, a PCB, TFT glass, an interposer, or the like, but the present invention is not limited thereto.

Further, the first electrode pad 11a may refer to an individual negative electrode, and the second electrode pad 11b may refer to a common positive electrode. For example, after three epitaxial dies emitting blue, green, and red light are respectively placed on three individual negative electrodes and bonded to form a single pixel, each of the epitaxial dies may be electrically connected the common positive electrode.

The epitaxial die 100 is placed on the first electrode pad 11a of the substrate part 11 such that a bonding pad layer 170 comes into contact with the first electrode pad 11a, and includes a light-emitting part 120, a first ohmic electrode 130, a passivation layer 150, a contact electrode 160, and a bonding pad layer 170.

Here, the light-emitting part 120 configured to generate red light, the first ohmic electrode 130, the passivation layer 150, the contact electrode 160, and the bonding pad layer 170 are the same as those of the above-described epitaxial die 100 for a semiconductor light-emitting device according to the first embodiment of the present invention, and thus redundant descriptions will be omitted.

Meanwhile, after the intermediate temporary substrate 190 is separated, the temporary bonding layer 180 is etched and removed, thereby exposing the contact electrode 160.

The bonding layer 12 electrically connects the first electrode pad 11a of the substrate part 11 and the bonding pad layer 170 of the epitaxial die 100 by bonding them together, and may include low melting point metals and noble metals such as gold (Au), silver (Ag), copper (Cu), and palladium (Pd) similar to or the same as the bonding pad layer 170 of the epitaxial die 100, but the present invention is not limited thereto.

The extension electrode 13 electrically connects the second electrode pad 11b of the substrate part 11 to the contact electrode 160 of the epitaxial die 100, and is formed to extend vertically from an upper portion of the second electrode pad 11b to above the mold part 14 through a through hole H of the mold part 14, which will be described below, and then extend horizontally by being bent toward the contact electrode 160 to come into contact with and be electrically connected to the contact electrode 160.

The extension electrode 13 may be formed of optically transparent and electrically conductive ceramics such as ITO, TiN, carbon nanotubes (CNT), and silver nanowires (Ag nanowires), or low melting point metals and noble metals such as gold (Au), silver (Ag), copper (Cu), and palladium (Pd) similar to or the same as the above-described materials of the bonding layer 12, but the present invention is not limited thereto.

The mold part 14 surrounds and supports the epitaxial die 100 and the extension electrode 13, which are disposed to form a vertical structure, and is formed so that an upper surface of the extension electrode 13 is exposed. In the mold part 14, the through hole H is formed above the second electrode pad 11b, and the extension electrode 13 is electrically connected to the second electrode pad 11b and the contact electrode 160 through the through hole H.

Meanwhile, laser drilling may be used to form the through hole H, and in this case, the mold part 14 may be made of materials that enable laser direct structuring (LDS) or laser direct imaging (LDI).

The black matrix (BM) 15 covers the exposed upper surfaces of the extension electrode 13 and the mold part 14, and may be formed using photolithography and spin coating processes, but the present invention is not limited thereto.

In addition, the black matrix 15 may be formed of a metal thin film or carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a high molecular weight block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S100) of manufacturing the epitaxial die for a semiconductor light-emitting device according to the first embodiment of the present invention will be described in detail.

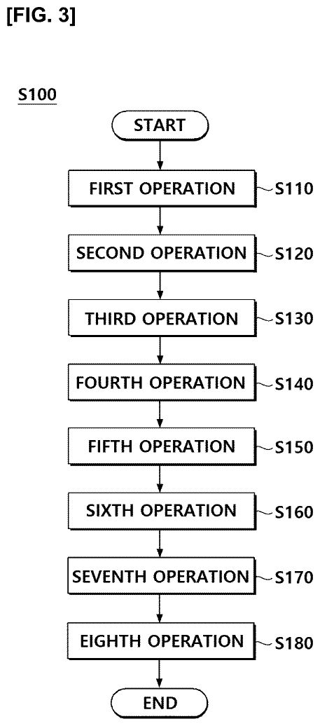

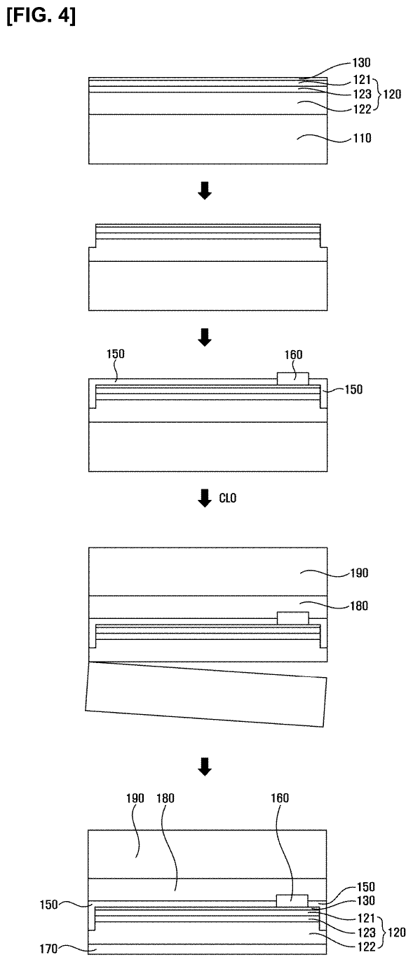

FIG. 3 is a flowchart of the method of manufacturing the epitaxial die for a semiconductor light-emitting device according to the first embodiment of the present invention, and FIG. 4 illustrates a process of manufacturing the epitaxial die for a semiconductor light-emitting device according to the first embodiment of the present invention.

As shown in FIGS. 3 and 4, the method (S100) of manufacturing the epitaxial die for a semiconductor light-emitting device according to the first embodiment of the present invention includes a first operation S110, a second operation S120, a third operation S130, a fourth operation S140, a fifth operation S150, a sixth operation S160, a seventh operation S170, and an eighth operation S180. However, it is of course possible that the order of the processes shown in FIGS. 3 and 4 can be changed.

The first operation S110 is an operation of preparing an initial growth substrate 110 and an intermediate temporary substrate 190. The initial growth substrate 110 is a substrate on which a light-emitting part 120 to be described below is epitaxially grown, and the initial growth substrate 110 made of gallium arsenide (GaAs) may be used.

The intermediate temporary substrate 190 is bonded to a passivation layer 150 by a temporary bonding layer 180, which will be described below, and supports the light-emitting part 120, a first ohmic electrode 130, the passivation layer 150, a contact electrode 160, and a bonding pad layer 170, and may include sapphire, or glass that has been adjusted to have a difference in thermal expansion coefficient of 2 ppm or less from the initial growth substrate 110.

Meanwhile, in the present invention, after the epitaxial die 100 of the present invention is finally completed, the intermediate temporary substrate 190 functions as a final support substrate that supports the light-emitting part 120, the first ohmic electrode 130, the passivation layer 150, the contact electrode 160, and the bonding pad layer 170.

The second operation S120 is an operation of forming the light-emitting part 120, which generates red light, on the initial growth substrate 110. That is, more specifically, the light-emitting part 120 includes a first semiconductor region 121 (e.g., a p-type semiconductor region), an active region 123 (e.g., MQWs), and a second semiconductor region 122 (e.g., an n-type semiconductor region), and in the second operation S120, the second semiconductor region 122, the active region 123, and the first semiconductor region 121 are epitaxially grown in this order on the initial growth substrate 110.

The third operation S130 is an operation of forming the first ohmic electrode 130 that is electrically connected to the first semiconductor region 121 by covering so as to come into surface contact with an upper surface of the first semiconductor region 121 of the light-emitting part 120. At this time, heat treatment is selectively performed at a high temperature of 300° C. or higher so that the first semiconductor region 121 forms a p-ohmic contact with the first ohmic electrode 130.

The fourth operation S140 is an operation of etching both sides of each of the light-emitting part 120 and the first ohmic electrode 130 to a predetermined depth and forming the passivation layer 150, which covers the first ohmic electrode 130 from the etched portions on both sides of the light-emitting part 120.

The fifth operation S150 is an operation of etching a portion of the passivation layer 150 to expose the first ohmic electrode 130 and forming the contact electrode 160 to come into contact with the exposed first ohmic electrode 130.

The sixth operation S160 is an operation of bonding the intermediate temporary substrate 190 and the passivation layer 150 in which the contact electrode 160 is exposed, through the temporary bonding layer 180. Due to the shape of the temporary bonding layer 180 that encloses the contact electrode 160, the contact electrode 160 is interposed between the temporary bonding layer 180 and the first ohmic electrode 130 and thus is not exposed.

The seventh operation S170 is an operation of removing the initial growth substrate 110. At this time, in the seventh operation S170, the growth substrate 110 may be separated from the light-emitting part 120, i.e., the second semiconductor region 122, using a CLO technique, thereby exposing an upper surface of the second semiconductor region 122. Here, the CLO technique refers to a technique of separating the light-emitting part 120 by completely etching the GaAs initial growth substrate 110 using an etching solution (NH4OH:H2O2) so that the above-described GaInP ESL is exposed.

The eighth operation S180 is an operation of forming the bonding pad layer 170 that is formed to come into contact with a lower surface of the light-emitting part 120 to be electrically connected to the light-emitting part 120, and functions as a vertical chip bonding pad. At this time, the bonding pad layer 170 is electrically connected to the lower surface of the light-emitting part through an n-ohmic contact and is exposed to the outside, thereby functioning as a negative electrode. Meanwhile, in the eighth operation S180, the bonding pad layer 170 needs to be heat treated at a high temperature of 300° C. or higher to form an n-ohmic contact with the lower surface of the light-emitting part 120.

After the basic structure of the epitaxial die 100 is formed through the above-described first operation S110 to eighth operation S180, processes such as grinding, dicing, probing, and sorting are performed.

Hereinafter, with reference to the accompanying drawings, a method (S10) of manufacturing the semiconductor light-emitting device according to the first embodiment of the present invention will be described in detail.

The semiconductor light-emitting device 10 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 4, 9, 46, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using the temporary substrate 190 on which circuit wiring and driving element regions are not completed, but is not limited thereto, and will be described herein as being formed as the COB type for convenience of description.

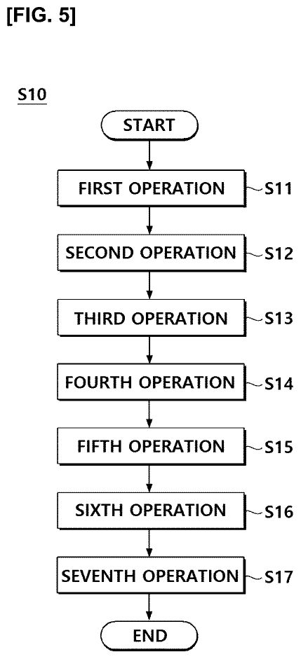

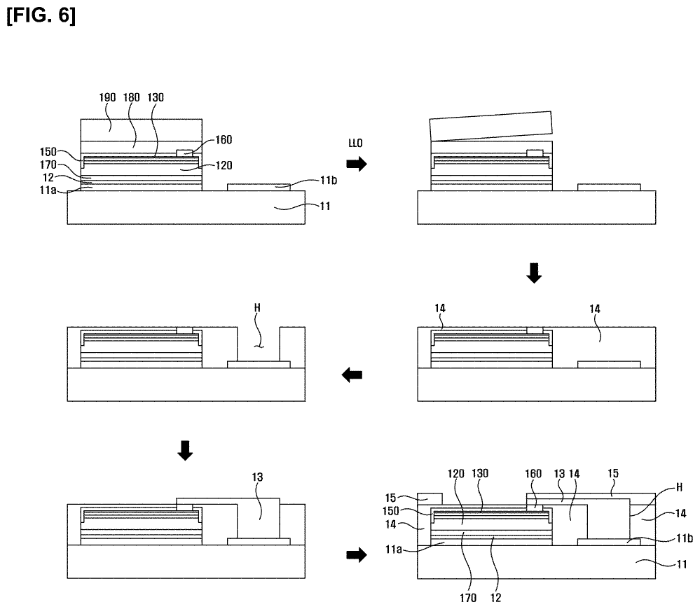

FIG. 5 is a flowchart of the method of manufacturing the semiconductor light-emitting device according to the first embodiment of the present invention, and FIG. 6 illustrates a process of manufacturing the semiconductor light-emitting device according to the first embodiment of the present invention.

As shown in FIGS. 5 and 6, the method (S10) of manufacturing the semiconductor light-emitting device according to the first embodiment of the present invention includes a first operation S11, a second operation S12, a third operation S13, a fourth operation S14, a fifth operation S15, a sixth operation S16, and a seventh operation S17. However, it is of course possible that the order of the processes shown in FIGS. 5 and 6 can be changed.

The first operation S11 is an operation of preparing the epitaxial die 100 for a semiconductor light-emitting device according to the first embodiment of the present invention and a substrate part 11 on which a first electrode pad 11a and a second electrode pad 11b are each formed. The substrate part 11 may refer to a semiconductor wafer, a PCB, TFT glass, an interposer, or the like, but the present invention is not limited thereto.

The second operation S12 is an operation of placing the epitaxial die 100 on the first electrode pad 11a, which is an individual negative electrode, and electrically connecting the first electrode pad 11a and the bonding pad layer 170 by bonding them through a bonding layer 12. At this time, the placement and bonding of the epitaxial die 100 can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 100, (2) an epitaxial die 100 with a ultra-small size of less than 50 μm×50 μm, and (3) an epitaxial die 100 having a self-assembly structure, additional masking media (such as a photoresist, ceramics (like glass, quartz, and alumina), or an invar fine metal mask (FMM) or processes may be employed before the placement and bonding of the epitaxial die 100.

The third operation S13 is an operation of separating the intermediate temporary substrate 190 of the epitaxial die 100 and etching the temporary bonding layer 180 to expose the contact electrode 160. At this time, in the third operation S13, the intermediate temporary substrate 190 may be separated from the temporary bonding layer 180 using an LLO technique. Here, the LLO technique refers to a technique of separating the intermediate temporary substrate 190 from the temporary bonding layer 180 by irradiating a rear surface of the transparent intermediate temporary substrate 190 with a UV laser beam having a uniform output and beam profile, and a single wavelength.

The fourth operation S14 is an operation of forming a mold part 14 surrounding the epitaxial die 100 so that the contact electrode 160 is exposed. At this time, the mold part 14 may be made of materials that enable LDS or LDI to allow laser drilling in the fifth operation S15 to be described below.

The fifth operation S15 is an operation of etching the mold part 14 to expose the second electrode pad 11b. That is, in the fifth operation S15, a through hole H is formed above the second electrode pad 11b by etching the mold part 14 above the second electrode pad 11b using laser drilling.

The sixth operation S16 is an operation of forming an extension electrode 13 that electrically connects the second electrode pad 11b and the exposed contact electrode 160. That is, the extension electrode 13 is formed to extend vertically from an upper portion of the second electrode pad 11b to above the mold part 14 through the through hole H, and then extend horizontally by being bent toward the contact electrode 160 to come into contact with and be electrically connected to the contact electrode 160.

The seventh operation S17 is an operation of forming a black matrix 15 that covers the extension electrode 13 and the mold part 14. The black matrix 15 may be formed using photolithography and spin coating processes, but the present invention is not limited thereto.

Hereinafter, with reference to the accompanying drawings, an epitaxial die 200 for a semiconductor light-emitting device according to a second embodiment of the present invention will be described in detail.

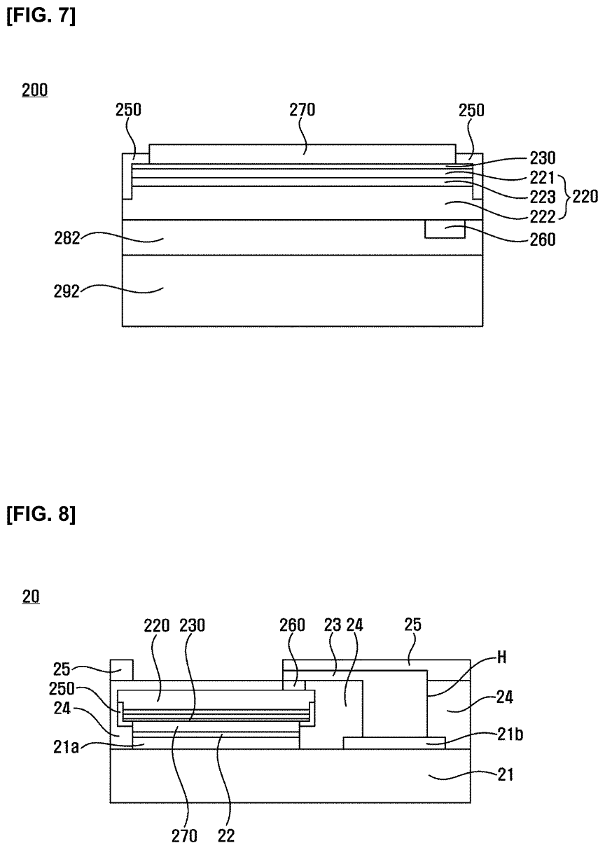

FIG. 7 illustrates an overall view of the epitaxial die for a semiconductor light-emitting device according to the second embodiment of the present invention.

As shown in FIG. 7, the epitaxial die 200 for a semiconductor light-emitting device according to the second embodiment of the present invention includes a light-emitting part 220, a first ohmic electrode 230, a passivation layer 250, a contact electrode 260, a bonding pad layer 270, a temporary bonding layer 280, and an intermediate temporary substrate 290.

Here, the temporary bonding layer 280 includes a first temporary bonding layer 281 and a second temporary bonding layer 282, and the intermediate temporary substrate 290 includes a first intermediate temporary substrate 291 and a second intermediate temporary substrate 292.

The light-emitting part 220 generates light, and in the present invention, in order to emit red light, binary, ternary, and quaternary compounds of Group III (Al, Ga, and In) phosphide semiconductors, such as indium phosphide (InP), indium gallium phosphide (InGaP), gallium phosphide (GaP), aluminum indium phosphide (AlInP), aluminum gallium phosphide (AlGaP), aluminum phosphide (AlP), and aluminum gallium indium phosphide (AlGaInP), are placed in appropriate positions and sequences on an initial growth substrate 210 and epitaxially grown (in the structure of the epitaxial die 200 of the present invention, the initial growth substrate 210 is first separated after bonding to the first intermediate temporary substrate 291, and then the second intermediate temporary substrate 292 is bonded and the first intermediate temporary substrate 291 is separated).

In particular, in order to emit red light, a high-quality Group III phosphide semiconductor with a high indium (In) composition, such as indium gallium phosphide (InGaP), should preferably be formed on Group III phosphide semiconductors composed of gallium phosphide (GaP), aluminum indium phosphide (AlInP), aluminum gallium phosphide (AlGaP), aluminum phosphide (AlP), and aluminum gallium indium phosphide (AlGaInP), but the present invention is not limited thereto.

More specifically, the light-emitting part 220 includes a first semiconductor region 221 (e.g., a p-type semiconductor region), an active region 223 (e.g., MQWs), and a second semiconductor region 222 (e.g., an n-type semiconductor region), and the light-emitting part 220 may have a structure in which the second semiconductor region 222, the active region 223, and the first semiconductor region 221 are epitaxially grown in this order on the initial growth substrate 210, and ultimately, may have an overall thickness typically ranging from about 5.0 to 8.0 μm, including multiple layers of group III phosphides, but the present invention is not limited thereto.

Each of the first semiconductor region 221, the active region 223, and the second semiconductor region 222 may be formed as either a single layer or multiple layers, and although not shown in the drawing, necessary layers such as buffer regions may be added before epitaxially growing the light-emitting part 220 on the gallium arsenide (GaAs) initial growth substrate 210 to ensure the high quality of the epitaxially grown light-emitting part 220. For example, the buffer regions may include a nucleation layer and a compliant layer composed of an un-doped semiconductor region to relieve stress and improve thin-film quality and typically have a thickness of about 4.0 μm. In addition, since the initial growth substrate 210 must be removed using a CLO technique, it is preferable to grow an ESL composed of gallium indium phosphide (GaInP) as a single-crystal thin film with a thickness of about 200 nm directly on the GaAs initial growth substrate 210 before the doped first semiconductor region 221 or second semiconductor region 222 is formed.

The second semiconductor region 222 has a second conductivity type (n-type), and is formed on the initial growth substrate 210. The second semiconductor region 222 is primarily composed of gallium arsenide (GaAs) and aluminum gallium indium phosphide (AlGaInP) semiconductors, and may have a thickness ranging from 2.0 to 3.5 μm.

The active region 223 generates light, i.e., red light, by using the recombination of electrons and holes, and is formed on the second semiconductor region 222. The active region 223 is composed of multiple layers of semiconductors, including primarily gallium indium phosphide (GaInP) and aluminum gallium indium phosphide (AlGaInP), and may have a thickness of several tens of nanometers (nm).

The first semiconductor region 221 has a first conductivity type (p-type), and is formed on the active region 223. The first semiconductor region 221 is composed of multiple layers of semiconductors, including primarily aluminum indium phosphide (AlInP), aluminum gallium indium phosphide (AlGaInP), and gallium phosphide (GaP), and may have a thickness ranging from several tens of nanometers (nm) to several micrometers (um).

That is, the active region 223 is interposed between the first semiconductor region 221 and the second semiconductor region 222, and generates light when holes in the first semiconductor region 221, which is a p-type semiconductor region, and electrons in the second semiconductor region 222, which is an n-type semiconductor region, recombine in the active region 223.

Meanwhile, the light-emitting part 220, which is epitaxially grown on the initial growth substrate 210 in the order of the second semiconductor region 222, the active region 223, and the first semiconductor region 221 is implemented by a process in which the first intermediate temporary substrate 291, which is made of sapphire, is bonded to the first semiconductor region 221 through the first temporary bonding layer 281, and the initial growth substrate 210 is separated, and then, the second intermediate temporary substrate 292, which is also made of sapphire, is bonded to a lower surface of the second semiconductor region 222 through the second temporary bonding layer 282, resulting in a structure in which the second semiconductor region 222, the active region 223, and the first semiconductor region 221 are stacked in this order on the second intermediate temporary substrate 292.

At this time, both sides of the light-emitting part 220 formed on the initial growth substrate 210 may have a shape etched to a predetermined depth, and the predetermined depth may refer to a depth up to the second semiconductor region 222, but the present invention is not limited thereto.

The first ohmic electrode 230 is electrically connected to the first semiconductor region 221 of the light-emitting part 220 and is formed on the first semiconductor region 221 so as to cover and come into surface contact with an upper surface of the first semiconductor region 221. At this time, the first semiconductor region 221, which is a p-type semiconductor region, is electrically connected to the first ohmic electrode 230 through a p-ohmic contact.

Although the first ohmic electrode 230 may be basically formed solely of a material with high reflectance and excellent electrical conductivity, the first ohmic electrode 230 may also be formed in combination with a material that has high transparency, but the present invention is not limited thereto. The materials for the first ohmic electrode 230 with high reflectance described above may include metals such as Ag, Al, Rh, Pt, Ni, Pd, Ru, Cu, Au, AuBe, AgBe, and AlBe, and the materials for the first ohmic electrode 230 with high transparency described above may include indium tin oxide (ITO), zinc oxide (ZnO), indium zinc oxide (IZO), indium gallium zinc oxide (IGZO), titanium nitride (TiN), Ni(O)—Au, Ni(O)—AuBe, Ni(O)—Ag, and the like.

The passivation layer 250 covers the first ohmic electrode 230 from the etched portions on both sides of the light-emitting part 220, and a portion of the first ohmic electrode 230 is exposed as a portion of the passivation layer 250 is etched and is opened.

The passivation layer 250 may be implemented with electrically insulating materials, and may include a single layer or multiple layers including at least one material from among silicon oxide, silicon nitride, metallic oxides including Al2O3, and organic insulators.

The bonding pad layer 270 functions as a vertical chip die bonding pad and is formed on the first ohmic electrode 230, which is exposed by the partial opening of the passivation layer 250. The bonding pad layer 270 is electrically connected to the first ohmic electrode 230, is exposed to the outside, and functions as a positive electrode.

The bonding pad layer 270 may basically include low melting point metals and noble metals such as gold (Au), silver (Ag), copper (Cu), and palladium (Pd), but the present invention is not limited thereto. In addition, the above-described low melting point metals may be formed of metals such as In, Sn, Zn, and Pb alone or an alloy including these metals.

The contact electrode 260 is formed to come into contact with a lower surface of the light-emitting part 220 to be electrically connected to the light-emitting part 220, and in this case, the contact electrode 260 is electrically connected to a lower surface of the second semiconductor region 222, which is an n-type semiconductor region, through an n-ohmic contact, and functions as a negative electrode.

The materials for the contact electrode 260 are not limited as long as they are compatible with the lower surface of the second semiconductor region 222, which is an n-type semiconductor region, and may include Ti, TiN, Cr, CrN, V, VN, NiCr, Al, Rh, Pt, Ni, Pd, Ru, Cu, Ag, Au, NiO, AuGe, and the like.

Meanwhile, although not shown in the drawing, before bonding the intermediate temporary substrate 290 on the lower surface of the light-emitting part 220, a surface texture pattern with a predetermined shape or an irregular shape may be formed on the lower surface of the second semiconductor region 222 to extract as much light generated in the active region 223 into the air as possible.

The temporary bonding layer 280 (i.e., the second temporary bonding layer 282) bonds the lower surface of the light-emitting part 220, on which the contact electrode 260 is formed, and the intermediate temporary substrate 290 to each other, and is formed on the lower surface of the light-emitting part 220 to cover the contact electrode 260. Due to the shape of the temporary bonding layer 280 that encloses the contact electrode 260, the contact electrode 260 is interposed between the temporary bonding layer 280 and the light-emitting part 220 and thus is not exposed.

The temporary bonding layer 280 may include materials such as benzocyclobutene (BCB), SU-8 polymers, flowable oxides (FOx) such as spin-on-glass (SOG) and hydrogen silsesquioxane (HSQ), and alloys including low melting point metals (e.g., In, Sn, and Zn) and noble metals (e.g., Au, Ag, Cu, and Pd).

The intermediate temporary substrate 290 (i.e., the second intermediate temporary substrate 292) is bonded to the passivation layer 250 by the temporary bonding layer 280 to support the light-emitting part 220, the first ohmic electrode 230, the passivation layer 250, the contact electrode 260, and the bonding pad layer 270, and it is preferable that the intermediate temporary substrate 290 is formed of a material that has a thermal expansion coefficient equal or similar to that of the initial growth substrate 210 and is simultaneously optically transparent, as long as the difference in thermal expansion coefficient does not exceed 2 ppm. The most preferable materials for the intermediate temporary substrate 290 that meet these criteria may include sapphire, or glass that has been adjusted to have a difference in thermal expansion coefficient of 2 ppm or less from the initial growth substrate 210.

Meanwhile, in the present invention, the second intermediate temporary substrate 292 functions as a final support substrate that supports the light-emitting part 220, the first ohmic electrode 230, the passivation layer 250, the contact electrode 260, and the bonding pad layer 270 after the epitaxial die 200 of the present invention is finally completed. At this time, it is preferable that an LLO sacrificial separation layer (not shown), which is a functional material that can be easily separated and removed by an LLO technique in the process of a third operation of a method (S20) of manufacturing the semiconductor light-emitting device, which will be described below, is formed between the intermediate temporary substrate 290 and the temporary bonding layer 280. The above-described LLO sacrificial separation layer (not shown) may be made of materials such as ZnO, ITO, IZO, IGO, IGZO, InGaN, InGaON, GaON, TiN, SiO2, SiNx, and the like.

Accordingly, the epitaxial die 200 for a semiconductor light-emitting device according to the second embodiment of the present invention has a form in which the contact electrode 260, which is a negative electrode, is interposed between the temporary bonding layer 280 and the light-emitting part 220 and thus is not exposed, and only the bonding pad layer 270, which functions as a positive electrode, is exposed to the outside.

Hereinafter, with reference to the accompanying drawings, a semiconductor light-emitting device 20 according to the second embodiment of the present invention will be described in detail.

The semiconductor light-emitting device 20 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 2, 9, 26, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using the intermediate temporary substrate 290 on which circuit wiring and driving element regions are not completed, but is not limited thereto, and will be described herein as being formed as the COB type for convenience of description.

FIG. 8 illustrates an overall view of the semiconductor light-emitting device according to the second embodiment of the present invention.

As shown in FIG. 8, the semiconductor light-emitting device 20 according to the second embodiment of the present invention includes a substrate part 21, the epitaxial die 200, a bonding layer 22, an extension electrode 23, a mold part 24, and a black matrix 25.

The substrate part 21 supports the epitaxial die 200 that is bonded thereto, and a first electrode pad 21a and a second electrode pad 21b are each formed on an upper surface of the substrate part 21. The substrate part 21 may refer to a semiconductor wafer, a PCB, TFT glass, an interposer, or the like, but the present invention is not limited thereto.

Further, the first electrode pad 21a may refer to an individual positive electrode, and the second electrode pad 21b may refer to a common negative electrode. For example, after three epitaxial dies emitting blue, green, and red light are respectively placed on three individual positive electrodes and bonded to form a single pixel, each of the epitaxial dies may be electrically connected to the common negative electrode.

The epitaxial die 200 is placed upside down on the first electrode pad 21a of the substrate part 21 such that the bonding pad layer 270 comes into contact with the first electrode pad 21a, and includes a light-emitting part 220, a first ohmic electrode 230, a passivation layer 250, a contact electrode 260, and a bonding pad layer 270.

Here, the light-emitting part 220 configured to generate red light, the first ohmic electrode 230, the passivation layer 250, the contact electrode 260, and the bonding pad layer 270 are the same as those of the above-described epitaxial die 200 for a semiconductor light-emitting device according to the second embodiment of the present invention, and thus redundant descriptions will be omitted.

Meanwhile, in the light-emitting part 220, after the intermediate temporary substrate 290 is separated, the temporary bonding layer 280 is etched and removed, thereby exposing the contact electrode 260.

Meanwhile, in the upside-down epitaxial die 200, a surface texture pattern of a predetermined shape or an irregular shape may be formed on an upper surface of the light-emitting part 220, i.e., an upper surface of the second semiconductor region 222, in order to extract as much light generated in the active region 223 into the air as possible.

The bonding layer 22 electrically connects the first electrode pad 21a of the substrate part 21 and the bonding pad layer 270 of the epitaxial die 200 by bonding them together, and may include low melting point metals and noble metals such as gold (Au), silver (Ag), copper (Cu), and palladium (Pd) similar to or the same as the bonding pad layer 270 of the epitaxial die 200, but the present invention is not limited thereto.

The extension electrode 23 electrically connects the second electrode pad 21b of the substrate part 21 to the contact electrode 260 of the epitaxial die 200, and is formed to extend vertically from an upper portion of the second electrode pad 21b to above the mold part 24 through a through hole H of the mold part 24, which will be described below, and then extend horizontally by being bent toward the contact electrode 260 to come into contact with and be electrically connected to the contact electrode 260.

The extension electrode 23 may be formed of optically transparent and electrically conductive ceramics such as ITO, TiN, carbon nanotubes (CNT), and silver nanowires (Ag nanowires), or low melting point metals and noble metals such as gold (Au), silver (Ag), copper (Cu), and palladium (Pd) similar to or the same as the above-described materials of the bonding layer 22, but the present invention is not limited thereto.

The mold part 24 surrounds and supports the epitaxial die 200 and the extension electrode 23, which are disposed to form a vertical structure, and is formed so that an upper surface of the extension electrode 23 is exposed. In the mold part 24, the through hole H is formed above the second electrode pad 21b, and the extension electrode 23 is electrically connected to the second electrode pad 21b and the contact electrode 260 through the through hole H.

Meanwhile, laser drilling may be used to form the through hole H, and in this case, the mold part 24 may be made of materials that enable LDS or LDI.

The black matrix (BM) 25 covers the exposed upper surfaces of the extension electrode 23 and the mold part 24, and may be formed using photolithography and spin coating processes, but the present invention is not limited thereto.

In addition, the black matrix 25 may be formed of a metal thin film or carbon-based organic material with an optical density of 3.5 or higher, but the present invention is not limited thereto. More specifically, representative examples thereof include a chromium (Cr) monolayer film, a chromium (Cr)/chromium oxide (CrOx) bilayer film, manganese dioxide (MnO2), an organic black matrix, graphite, and a pigment dispersion composition (prepared by blending a high molecular weight block copolymer resin with pigment-affinity groups such as amino, hydroxyl, and carboxyl groups, with carbon black as a medium, and mixing the blend with a solvent and a dispersing agent).

Hereinafter, with reference to the accompanying drawings, a method (S200) of manufacturing the epitaxial die for a semiconductor light-emitting device according to the second embodiment of the present invention will be described in detail.

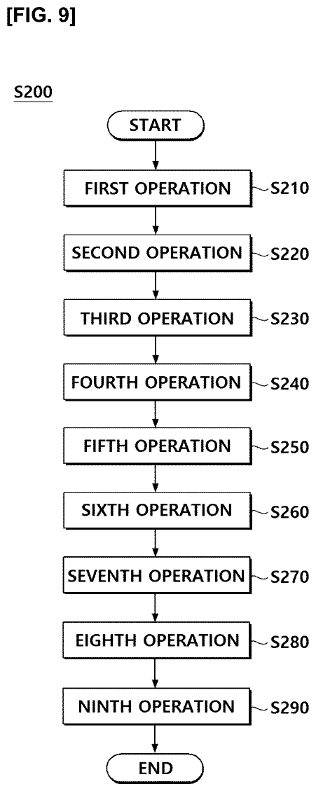

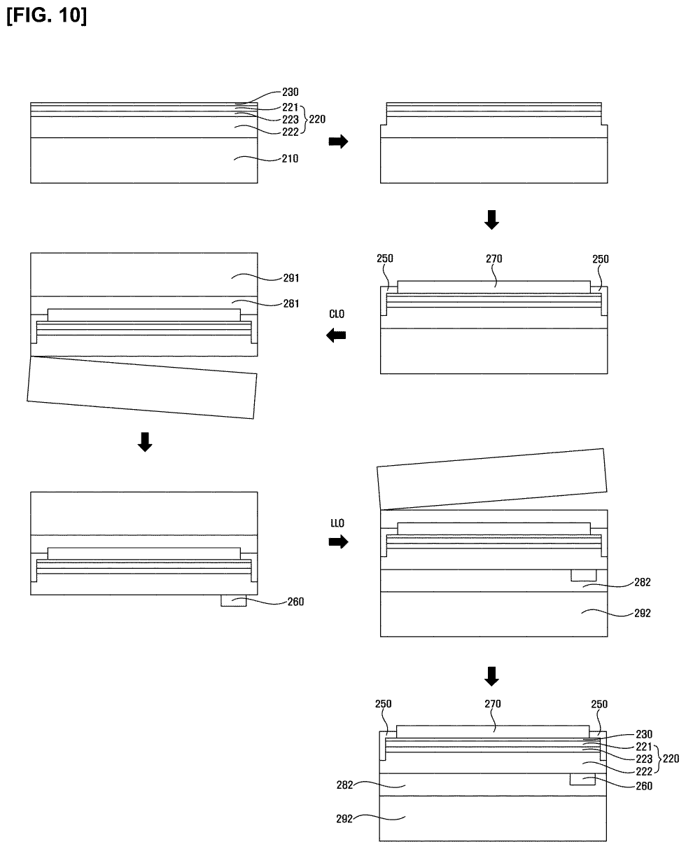

FIG. 9 is a flowchart of the method of manufacturing the epitaxial die for a semiconductor light-emitting device according to the second embodiment of the present invention, and FIG. 10 illustrates a process of manufacturing the epitaxial die for a semiconductor light-emitting device according to the second embodiment of the present invention.

As shown in FIGS. 9 and 10, the method (S200) of manufacturing the epitaxial die for a semiconductor light-emitting device according to the second embodiment of the present invention includes a first operation S210, a second operation S220, a third operation S230, a fourth operation S240, a fifth operation S250, a sixth operation S260, a seventh operation S270, an eighth operation S280, and a ninth operation S290. However, it is of course possible that the order of the processes shown in FIGS. 9 and 10 can be changed.

The first operation S210 is an operation of preparing an initial growth substrate 210, a first intermediate temporary substrate 291, and a second intermediate temporary substrate 292. The initial growth substrate 210 is a substrate on which a light-emitting part 220 to be described below is epitaxially grown, and the initial growth substrate 210 made of gallium arsenide (GaAs) may be used.

The first intermediate temporary substrate 291 and the second intermediate temporary substrate 292 are respectively bonded to lower surfaces of a passivation layer 250 and the light-emitting part 220 by a first temporary bonding layer 281 and a second temporary bonding layer 282, which will be described below, and the second intermediate temporary substrate 292 supports the light-emitting part 220, a first ohmic electrode 230, a passivation layer 250, a contact electrode 260, and a bonding pad layer 270, and may include sapphire, or glass adjusted to have a difference in thermal expansion coefficient of 2 ppm or less from the initial growth substrate 210.

Meanwhile, in the present invention, after the epitaxial die 200 of the present invention is finally completed, the second intermediate temporary substrate 292 functions as a final support substrate that supports the light-emitting part 220, the first ohmic electrode 230, the passivation layer 250, the contact electrode 260, and the bonding pad layer 270.

The second operation S220 is an operation of forming the light-emitting part 220, which generates red light, on the initial growth substrate 210, and forming the first ohmic electrode 230 that is electrically connected to a first semiconductor region 221 by covering so as to come into surface contact with an upper surface of the first semiconductor region 221 of the light-emitting part 220.

That is, more specifically, the light-emitting part 220 includes the first semiconductor region 221 (e.g., a p-type semiconductor region), an active region 223 (e.g., MQWs), and a second semiconductor region 222 (e.g., an n-type semiconductor region), and in the second operation S220, the second semiconductor region 222, the active region 223, and the first semiconductor region 221 are epitaxially grown in this order on the initial growth substrate 210.

Further, in the second operation S220, heat treatment is selectively performed at a high temperature of 300° C. or higher so that the first semiconductor region 221 forms a p-ohmic contact with the first ohmic electrode 230.

The third operation S230 is an operation of etching both sides of each of the light-emitting part 220 and the first ohmic electrode 230 to a predetermined depth and forming the passivation layer 250, which covers the first ohmic electrode 230 from the etched portions on both sides of the light-emitting part 220.

The fourth operation S240 is an operation of etching a portion of the passivation layer 250 to expose the first ohmic electrode 230 and forming the bonding pad layer 270, which functions as a vertical chip bonding pad, to come into contact with the exposed first ohmic electrode 230.

The fifth operation S250 is an operation of bonding the first intermediate temporary substrate 291 and the passivation layer 250, in which the bonding pad layer 270 is exposed, through the first temporary bonding layer 281.

The sixth operation S260 is an operation of removing the initial growth substrate 210. At this time, in the sixth operation S260, the initial growth substrate 210 may be separated from the light-emitting part 220, i.e., the second semiconductor region 222, using a CLO technique, thereby exposing an upper surface of the second semiconductor region 222. Here, the CLO technique refers to a technique of separating the light-emitting part 220 by completely etching the GaAs initial growth substrate 210 using an etching solution (NH4OH:H2O2) so that the above-described GaInP ESL is exposed.

The seventh operation S270 is an operation of forming the contact electrode 260 that is formed to come into contact with a lower surface of the light-emitting part 220 to be electrically connected to the light-emitting part 220. In this case, the contact electrode 260 is electrically connected to the lower surface of the second semiconductor region 222, which is an n-type type semiconductor region, through an n-ohmic contact and functions as a negative electrode. Meanwhile, in the seventh operation S270, the contact electrode 260 needs to be heat treated at a high temperature of 300° C. or higher to form an n-ohmic contact with the lower surface of the light-emitting part 220.

The eighth operation S280 is an operation of bonding the second intermediate temporary substrate 292 to the lower surface of the light-emitting part 220, in which the contact electrode 260 is exposed, through the second temporary bonding layer 282. Due to the shape of the second temporary bonding layer 282 that encloses the contact electrode 260, the contact electrode 260 is interposed between the second temporary bonding layer 282 and the light-emitting part 220 and thus is not exposed.

The ninth operation S290 is an operation of removing the first intermediate temporary substrate 291, and etching the first temporary bonding layer 281 to expose the bonding pad layer 270. In this case, in the ninth operation S290, the first intermediate temporary substrate 291 may be separated from the first temporary bonding layer 281 using an LLO technique.

After the basic structure of the epitaxial die 200 is formed through the above-described first operation S210 to ninth operation S290, processes such as grinding, dicing, probing, and sorting are performed.

Hereinafter, with reference to the accompanying drawings, a method (S20) of manufacturing the semiconductor light-emitting device according to the second embodiment of the present invention will be described in detail.

The semiconductor light-emitting device 20 of the present invention may be formed as a COB in which individual chips or epitaxial die units are directly transferred and connected to a substrate (such as a semiconductor wafer, a PCB, or TFT glass) on which circuit wiring and driving element regions are completed, a POB in which package units (including 1, 2, 2, 9, 26, . . . , and n2 chips or epitaxial die units) manufactured using a fan-out package process known in conventional memory semiconductor technology are directly transferred and connected to a substrate on which circuit wiring and driving element regions (such as a semiconductor wafer, a PCB, or TFT glass) are completed, or an interposer using a intermediate temporary substrate 290 on which circuit wiring and driving element regions are not completed, but is not limited thereto, and will be described herein as being formed as the COB type for convenience of description.

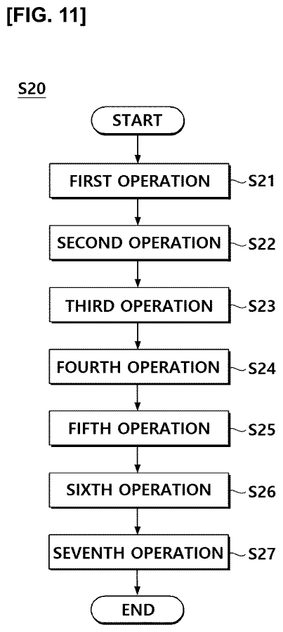

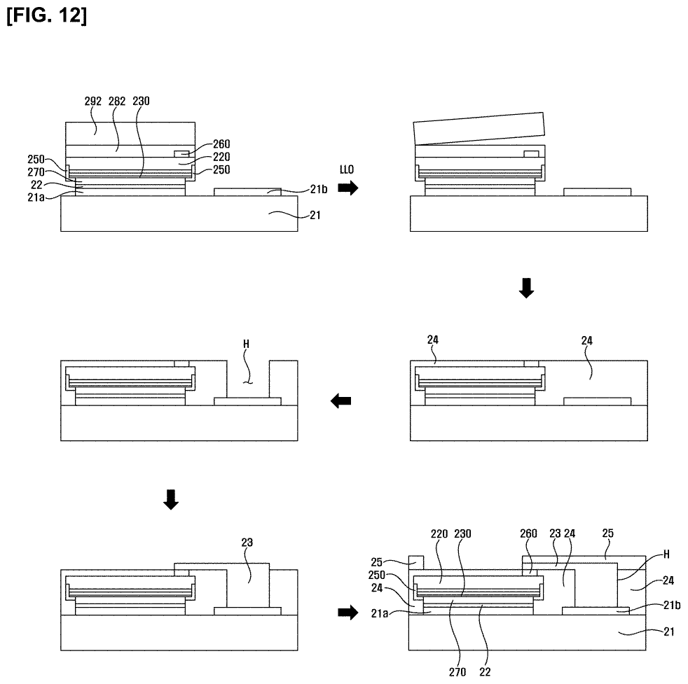

FIG. 11 is a flowchart of the method of manufacturing the semiconductor light- emitting device according to the second embodiment of the present invention, and FIG. 12 illustrates a process of manufacturing the semiconductor light-emitting device according to the second embodiment of the present invention.

As shown in FIGS. 11 and 12, the method (S20) of manufacturing the semiconductor light-emitting device according to the second embodiment of the present invention includes a first operation S21, a second operation S22, a third operation S23, a fourth operation S24, a fifth operation S25, a sixth operation S26, and a seventh operation S27. However, it is of course possible that the order of the processes shown in FIGS. 11 and 12 can be changed.

The first operation S21 is an operation of preparing the epitaxial die 200 for a semiconductor light-emitting device according to the second embodiment of the present invention and a substrate part 21 on which a first electrode pad 21a and a second electrode pad 21b are each formed. The substrate part 21 may refer to a semiconductor wafer, a PCB, TFT glass, an interposer, or the like, but the present invention is not limited thereto.

The second operation S22 is an operation of placing the epitaxial die 200 upside down on the first electrode pad 21a, which is an individual negative electrode, and electrically connecting the first electrode pad 21a and the bonding pad layer 270 by bonding them through a bonding layer 22. At this time, the placement and bonding of the epitaxial die 200 can be accomplished through typical chip die transfer processes such as pick-and-place, roll to roll (R2R), and stamps (made from materials such as polydimethylsiloxane (PDMS), silicon (Si), quartz, and glass), which are commonly known tools used in representative processes of massive transfer.

Meanwhile, when it is necessary to achieve objectives such as (1) high precision placement of an epitaxial die 200, (2) an epitaxial die 200 with a ultra-small size of less than 50 μm×50 μm, and (3) an epitaxial die 200 having a self-assembly structure, additional masking media (such as a photoresist, ceramics (like glass, quartz, and alumina), or an invar FMM or processes may be employed before the placement and bonding of the epitaxial die 200.

The third operation S23 is an operation of removing the intermediate temporary substrate 290 (i.e., the second intermediate temporary substrate 292) of the epitaxial die 200, and etching the temporary bonding layer 280 (i.e., the second temporary bonding layer 282) to expose the contact electrode 260. At this time, in the third operation S23, the intermediate temporary substrate 290 may be separated from the temporary bonding layer 280 using an LLO technique. Here, the LLO technique refers to a technique of separating the intermediate temporary substrate 290 from the temporary bonding layer 280 by irradiating a rear surface of the transparent intermediate temporary substrate 290 with a UV laser beam having a uniform output and beam profile, and a single wavelength.

The fourth operation S24 is an operation of forming a mold part 24 surrounding the epitaxial die 200 so that the contact electrode 260 is exposed. At this time, the mold part 24 may be made of materials that enable LDS or LDI to allow laser drilling in the fifth operation S25 to be described below.

The fifth operation S25 is an operation of etching the mold part 24 to expose the second electrode pad 21b. That is, in the fifth operation S25, a through hole H is formed above the second electrode pad 21b by etching the mold part 24 above the second electrode pad 21b using laser drilling.

The sixth operation S26 is an operation of forming an extension electrode 23 that electrically connects the second electrode pad 21b and the exposed contact electrode 260. That is, the extension electrode 23 is formed to extend vertically from an upper portion of the second electrode pad 21b to above the mold part 24 through the through hole H, and then extend horizontally by being bent toward the contact electrode 260 to come into contact with and be electrically connected to the contact electrode 260.

The seventh operation S27 is an operation of forming a black matrix 25 that covers the extension electrode 23 and the mold part 24. The black matrix 25 may be formed using photolithography and spin coating processes, but the present invention is not limited thereto.

Although all the components constituting the embodiments of the present invention have been described as being combined or combined to operate as one, the present invention is not necessarily limited to the embodiments. That is, one or more of all the components may be combined to operate as one within the scope of the present invention.

Further, since the terms, such as “comprising”, “including”, or “having” may mean that the corresponding component can be included unless otherwise stated, it should be construed that another component is not excluded but may be further included. Unless defined otherwise, all terms used herein, including technical or scientific terms, have the same meanings as those generally understood by those skilled in the art to which the present invention pertains. Commonly used terms, such as terms defined in dictionaries, should be interpreted as being consistent with the contextual meaning of the related art and are not interpreted in an ideal or excessively formal meaning unless explicitly defined herein.

In addition, the above description is merely an exemplary description of the technical spirit of the present invention, and the present invention may be subjected to various modifications and variations made by those skilled in the art to which the present invention pertains without departing from the essential features of the present invention.

Accordingly, the embodiments disclosed in the present invention are not provided to limit the technical spirit of the embodiments of the present invention but are provided to describe the present invention, and the scope of the technical spirit of the present invention is not limited by the embodiments. The scope of protection of the present invention should be construed by the attached claims, and all the technical ideas within the equivalent ranges fall within the scope of the present invention.

1. An epitaxial die for a semiconductor light-emitting device, wherein the epitaxial die is formed by separating into die units, and functions as a pixel after being individually transferred to a substrate part. comprising:
a light-emitting part configured to generate red light;
a first ohmic electrode formed on the light-emitting part and electrically connected to the light-emitting part;
a passivation layer formed to cover the first ohmic electrode, and having a portion opened to expose a portion of the first ohmic electrode;
a contact electrode formed on the exposed first ohmic electrode and electrically connected to the first ohmic electrode;
a temporary bonding layer formed over the contact electrode and the passivation layer to cover the contact electrode;
a temporary substrate bonded on the temporary bonding layer; and
a bonding pad layer formed to come into contact with a lower surface of the light-emitting part to be electrically connected to the light-emitting part and functioning as a vertical chip bonding pad and is exposed to the outside,
wherein the contact electrode is interposed between the temporary bonding layer and the first ohmic electrode and thus is not exposed is not exposed to the outside before the epitaxial die is transferred to the substrate part,
wherein the temporary substrate is optically transparent, and it is possible to determine optical defects of the epitaxial die before the epitaxial die is transferred to the substrate part.

2-8. (canceled)

9. The epitaxial die of claim 1, wherein the light-emitting part is etched on both sides to a preset depth, and the passivation layer covers the first ohmic electrode from the etched portion on both sides of the light-emitting part.

10. The epitaxial die of claim 1, wherein the light-emitting part includes:
a first semiconductor region having first conductivity;
a second semiconductor region having second conductivity that is different from the first conductivity; and
an active region interposed between the first semiconductor region and the second semiconductor region and configured to generate light using recombination of electrons and holes.

11. The epitaxial die of claim 1, wherein the bonding pad layer is electrically connected by making a negative ohmic contact (n-ohmic contact) to the lower surface of the light-emitting part.

12. A method of manufacturing an epitaxial die for a semiconductor light-emitting device, wherein the epitaxial die is formed by separating into die units, and functions as a pixel after being individually transferred to a substrate part, comprising:
a first operation of preparing a growth substrate and a temporary substrate;
a second operation of forming a light-emitting part, which generates red light, on the growth substrate;
a third operation of forming a first ohmic electrode on the light-emitting part;
a fourth operation of forming a passivation layer that covers the first ohmic electrode;
a fifth operation of etching a portion of the passivation layer to expose the first ohmic electrode and forming a contact electrode to come into contact with the exposed first ohmic electrode;
a sixth operation of bonding the temporary substrate and the passivation layer, in which the contact electrode is exposed, through a temporary bonding layer;
a seventh operation of separating the growth substrate; and
an eighth operation of forming a bonding pad layer formed to come into contact with a lower surface of the light-emitting part to be electrically connected to the light-emitting part and functioning as a vertical chip bonding pad,
wherein the temporary bonding layer formed over the contact electrode and the passivation layer to cover the contact electrode,
wherein the contact electrode is interposed between the temporary bonding layer and the first ohmic electrode and is not exposed to the outside before the epitaxial die is transferred to the substrate part,
wherein the temporary substrate is optically transparent, and it is possible to determine optical defects of the epitaxial die before the epitaxial die is transferred to the substrate part.

13. An epitaxial die for a semiconductor light-emitting device, wherein the epitaxial die is formed by separating into die units, and functions as a pixel after being individually transferred to a substrate part, comprising:
a light-emitting part configured to generate red light;
a first ohmic electrode formed on the light-emitting part and electrically connected to the light-emitting part;
a passivation layer formed to cover the first ohmic electrode, and having a portion opened to expose a portion of the first ohmic electrode;
a bonding pad layer formed on the exposed first ohmic electrode and electrically connected to the first ohmic electrode, and functioning as a vertical chip bonding pad;
a contact electrode formed to come into contact with a lower surface of the light-emitting part to be electrically connected to the light-emitting part, wherein the contact electrode is electrically connected by making a negative ohmic contact (n-ohmic contact) to the lower surface of the light-emitting part;
a temporary bonding layer formed on the lower surface of the light-emitting part to cover the contact electrode; and
a temporary substrate bonded to a lower surface of the temporary bonding layer,
wherein the contact electrode is interposed between the temporary bonding layer and the light-emitting part and is not exposed to the outside before the epitaxial die is transferred to the substrate part,
wherein the temporary substrate is optically transparent, and it is possible to determine optical defects of the epitaxial die before the epitaxial die is transferred to the substrate part.

14. The epitaxial die of claim 13, wherein the light-emitting part is etched on both sides to a preset depth, and the passivation layer covers the first ohmic electrode from the etched portion on both sides of the light-emitting part.

15. The epitaxial die of claim 13, wherein the light-emitting part includes:
a first semiconductor region having first conductivity;
a second semiconductor region having second conductivity that is different from the first conductivity; and
an active region interposed between the first semiconductor region and the second semiconductor region and configured to generate light using recombination of electrons and holes.
